(19) United States
(12) Patent Application Publication
(10) Pub. No.: US 2025/0141407 A1
(43) Pub. Date: May 1, 2025

(54) BIAS CIRCUIT AND LOW NOISE AMPLIFIER CIRCUIT INCLUDING THE SAME

(71) Applicant: Samsung Electro-Mechanics Co., Ltd., Suwon-si (KR)

(72) Inventors: Mooyoung RYU, Suwon-si (KR); Gyu-Suck KIM, Suwon-si (KR); Eungju KIM, Suwon-si (KR); Taeho LIM, Suwon-si (KR)

(73) Assignee: Samsung Electro-Mechanics Co., Ltd., Suwon-si (KR)

(21) Appl. No.: 18/600,924

(22) Filed: Mar. 11, 2024

(30) Foreign Application Priority Data
Oct. 27, 2023 (KR) 10-2023-0145896

(51) Int. Cl. H03F 1/30; H03F 1/02; H03F 1/22

(52) U.S. Cl. CPC H03F 1/301; H03F 1/0227; H03F 1/223; H03F 2200/294; H03F 2200/451

(57) ABSTRACT

A bias circuit and a low-noise amplifier circuit including the same provided. The bias circuit may be connected to a first transistor configured to amplify an input radio frequency (RF) signal and may be configured to provide a bias voltage to a second transistor that amplifies an output RF signal of the first transistor. The bias circuit may include a current source configured to receive a power supply voltage and generate a reference current, and a current-to-voltage conversion circuit configured to convert the reference current into the bias voltage and provide the bias voltage to a control terminal of the second transistor.

### CROSS-REFERENCE TO RELATED APPLICATIONS

This application claims the benefit under 35 USC § 119 (a) of Korean Patent Application No. 10-2023-0145896 filed on Oct. 27, 2023, in the Korean Intellectual Property Office, the entire disclosure of which is incorporated herein by reference for all purposes.

### BACKGROUND

### 1. Field

This following description relates to a bias circuit and a low noise amplifier circuit including the same.

### 2. Description of Related Art

The low noise amplifier (LNA) for reception in the front-end module (FEM) of a communication system may typically use a power supply voltage of 1.8V. However, in order to reduce the power consumption of the communication system, the power supply voltage is being lowered to 1.2V.

In current communication systems, power supply voltages are divided into 1.8V and 1.2V, and in some examples, power supply voltages of 1.8V and 1.2V are supported simultaneously.

Typically, a low noise amplifier may include a common source transistor and a common gate transistor having a cascode structure. A bias circuit of the common gate transistor applies a bias voltage using the power supply voltage, and the bias voltage when using a power supply voltage of 1.8V may be different form the bias voltage when using a power supply voltage of 1.2V. Therefore, a method that may provide a constant bias voltage even if the power supply voltage changes is desired.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a bias circuit, connected to a first transistor configured to amplify an input radio frequency (RF) signal, and configured to provide a bias voltage to a second transistor that amplifies an output RF signal of the first transistor includes a current source configured to receive a power supply voltage and generate a reference current; and a current-to-voltage conversion circuit configured to convert the reference current into the bias voltage and provide the bias voltage to a control terminal of the second transistor.

The current source may be configured to increase a magnitude of the reference current as temperature increases.

The current source may include a third transistor configured to have a first terminal connected to the power supply terminal that supplies the power supply voltage, and a second terminal connected to a ground through a resistor; and a fourth transistor connected to the third transistor in a current mirror structure and configured to generate the reference current by mirroring a current of the third transistor, wherein a resistance value of the resistor decreases as temperature increases.

The current source may further include an operation amplifier configured to have a first terminal to which a reference voltage is applied, a second terminal connected to the second terminal of the third transistor, and an output terminal connected to a control terminal of the third transistor and a control terminal of the fourth transistor, and configured to operate so that a voltage of the second terminal of the operational amplifier is equal to the reference voltage.

The current source may further include a fifth transistor configured to have a first terminal connected to the power supply terminal and connected to the third transistor in a current mirror structure; a sixth transistor configured to have a first terminal connected to the second terminal of the third transistor, a second terminal connected to the resistor, and a control terminal connected to a second terminal of the fifth transistor; and a seventh transistor connected between the second terminal of the fifth transistor and the ground, and configured to have a control terminal connected to the second terminal of the sixth transistor.

The current source may further include a fifth transistor configured to have a first terminal connected to the power supply terminal and connected to the third transistor in a current mirror structure; a sixth transistor diode-connected between a second terminal of the fifth transistor and the ground; and a seventh transistor configured to have a first terminal connected to the second terminal of the third transistor, a second terminal connected to the resistor, and a control terminal connected to a control terminal of the sixth transistor.

The current-to-voltage conversion circuit may further include a plurality of resistors connected in series between the current source and a ground; and a plurality of switches connected between one end of each of the plurality of resistors and a control terminal of the second transistor.

The current-to-voltage conversion circuit may further include a plurality of diodes connected in series between the current source and a ground; and a plurality of switches connected between one end of each of the plurality of diodes and a control terminal of the second transistor.

In a general aspect, a low noise amplifier circuit includes a common source transistor configured to amplify an input radio frequency (RF) signal and output an amplified RF signal; a common gate transistor, connected to the common source transistor with a cascode structure, configured to operate based on a bias voltage input to a control terminal, and configured to amplify and output an output RF signal of the common source transistor; and a bias circuit configured to generate a reference current from a power supply voltage and configured to generate the bias voltage with the reference current.

The bias circuit may include a current source configured to receive the power supply voltage and configured to generate the reference current; and a current-to-voltage conversion circuit configured to convert the reference current into the bias voltage and configured to provide the bias voltage to a control terminal of the common gate transistor, wherein the current source is configured to increase a magnitude of the reference current as temperature increases.

The current source may include a third transistor configured to have a first terminal connected to the power supply terminal that supplies the power supply voltage, and a second terminal connected to a ground through a resistor; and a fourth transistor connected to the third transistor in a current mirror structure and configured to generate the reference current by mirroring a current of the third transistor, wherein a resistance value of the resistor decreases as temperature increases.

The current source may further include an operation amplifier configured to have a first terminal to which a reference voltage is applied, a second terminal connected to the second terminal of the third transistor, and an output terminal connected to a control terminal of the third transistor and a control terminal of the fourth transistor, and configured to operate so that the voltage of the second terminal is equal to the reference voltage.

The current source may further include a fifth transistor configured to have a first terminal connected to the power supply terminal and connected to the third transistor in a current mirror structure; a sixth transistor configured to have a first terminal connected to the second terminal of the third transistor, a second terminal connected to the resistor, and a control terminal connected to a second terminal of the fifth transistor; and a seventh transistor connected between the second terminal of the fifth transistor and ground, and configured to have a control terminal connected to the second terminal of the sixth transistor.

The current source may further include a fifth transistor configured to have a first terminal connected to the power supply terminal and connected to the third transistor in a current mirror structure; a sixth transistor diode-connected between a second terminal of the fifth transistor and the ground; and a seventh transistor configured to have a first terminal connected to the second terminal of the third transistor, a second terminal connected to the resistor, and a control terminal connected to a control terminal of the sixth transistor.

The current-to-voltage conversion circuit may include a plurality of resistors connected between the current source and ground, and configured to convert the reference current into the bias voltage, and the bias voltage is generated by at least some of the plurality of resistors.

Other features and aspects will be apparent from the following detailed description, the drawings, and the claims.

### BRIEF DESCRIPTION OF DRAWINGS

FIG. 1 is a diagram schematically illustrating an example low noise amplifier circuit, in accordance with one or more embodiments.

FIG. 2 is a circuit diagram illustrating an example of the current source illustrated in FIG. 1.

FIG. 3 is a circuit diagram illustrating another example of the current source illustrated in FIG. 1.

FIG. 4 is a circuit diagram illustrating another example of the current source illustrated in FIG. 1.

FIG. 5 is a circuit diagram illustrating another example of the current source illustrated in FIG. 1.

FIG. 6 is a diagram illustrating an example of the current-to-voltage conversion circuit shown in FIG. 1.

FIG. 7 is a diagram illustrating another example of the current-to-voltage conversion circuit shown in FIG. 1.

FIG. 8 is a diagram illustrating another example of the current-to-voltage conversion circuit illustrated in FIG. 1.

FIG. 9 is a diagram illustrating an example bias circuit having a voltage source, in accordance with one or more embodiments.

FIG. 10 is a diagram illustrating gate bias voltages provided from the bias circuit shown in FIG. 9 and the bias circuit shown in FIG. 1, respectively.

FIG. 11 is a graph illustrating the gain characteristics of the LNA circuit including the bias circuit shown in FIG. 9 and the gain characteristic of the LNA circuit including the bias circuit shown in FIG. 1.

FIG. 12 is a diagram illustrating the gate bias voltages provided by the bias circuit shown in FIG. 9 and the bias circuit shown in FIG. 6, respectively, according to temperature.

FIG. 13 is a graph illustrating the gain characteristics of the LNA circuit including the bias circuit shown in FIG. 9 and the LNA circuit including the bias circuit shown in FIG. 1 according to temperature.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

Throughout the one or more examples, a radio frequency (RF) signal may have a format according to other random wireless and wired protocols designated by, as only examples, Wi-Fi (IEEE 802.11 family, etc.), WiMAX (IEEE 802.16 family, etc.), IEEE 802.20, long term evolution (LTE), Evolution-Data Optimized (Ev-DO), high-speed packet access plus (HSPA+), high-speed downlink packet access plus (HSDPA+), high-speed uplink packet access plus (HSUPA+), Enhanced Data GSM Evolution (EDGE), Global System for Mobile communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other wireless and wired protocols designated thereafter, but is not limited thereto.

One or more examples may provide a bias circuit that provides a constant bias voltage and a low noise amplifier circuit including the bias circuit.

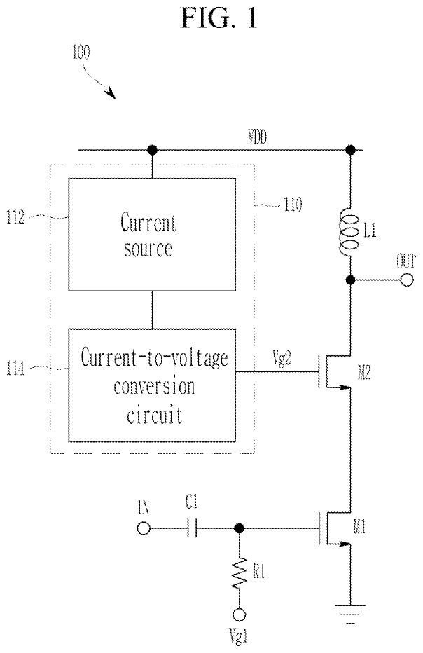

FIG. 1 is a diagram schematically illustrating an example low noise amplifier circuit, in accordance with one or more embodiments.

Referring to FIG. 1, a low noise amplifier (LNA) circuit 100 may include a transistor M1 and a transistor M2 connected between an input terminal IN and an output terminal OUT. The LNA circuit 100 may further include a coupling capacitor C1, a resistor R1, and an inductor L1.

In the LNA circuit 100, in accordance with one or more embodiments, the transistor M1 and transistor M2 may be connected in a cascode structure. In an example, the transistor M1 may be a common source transistor, and the transistor M2 may be a common gate transistor.

A gate of transistor M1 may be connected to the input terminal IN.

The coupling capacitor C1 may be connected between the gate of the transistor M1 and the input terminal IN, and a gate bias voltage Vg1 may be applied to the gate of the transistor M1 through the resistor R1.

A source of transistor M1 may be connected to ground, and a drain of transistor M1 may be connected to a source of transistor M2.

A drain of the transistor M2 may be connected to the output terminal OUT, and a gate bias voltage Vg2 may be applied to a gate of the transistor M2. Additionally, the inductor L1 may be connected between the drain of the transistor M2 and a power supply voltage source that supplies the power supply voltage VDD, and the power supply voltage VDD may be provided to the drain of the transistor M2 through the inductor L1.

The RF signal may be input to the gate of the transistor M1 through the coupling capacitor C1, the RF signal may be amplified by the transistor M1 and the transistor M2, and the amplified RF signal may be output to the output terminal OUT.

In an example, a bias circuit 110 may be connected to the gate of the transistor M2, may generate a constant gate bias voltage Vg2 from the power supply voltage VDD, and may provide the gate bias voltage Vg2 to the gate of the transistor M2.

The bias circuit 110 may include a current source 112 and a current-to-voltage conversion circuit 114.

The current source 112 may supply a constant current from the power supply voltage VDD. In an example, the current source 112 may have proportional to absolute temperature (PTAT) characteristics that increase the magnitude of current as temperature increases.

The current-to-voltage conversion circuit 114 may convert the current supplied from the current source 112 into a voltage and provide the converted voltage as the gate bias voltage Vg2 to the gate of the transistor M2.

Accordingly, the bias circuit 110 may generate a constant current through the current source 112 even if the power supply voltage VDD changes, and thus a constant gate bias voltage Vg2 may be provided to the gate of the transistor M2 even when various power supply voltages VDD are supplied.

Typically, the gain characteristics of an LNA circuit decrease as the temperature increases, and the gain characteristics increase as the temperature decreases. Therefore, the bias circuit 110 according to the embodiment may provide a larger gate bias voltage Vg2 as the temperature increases by increasing the magnitude of the current as the temperature increases, thereby compensating for the performance of the LNA circuit due to the increase in temperature.

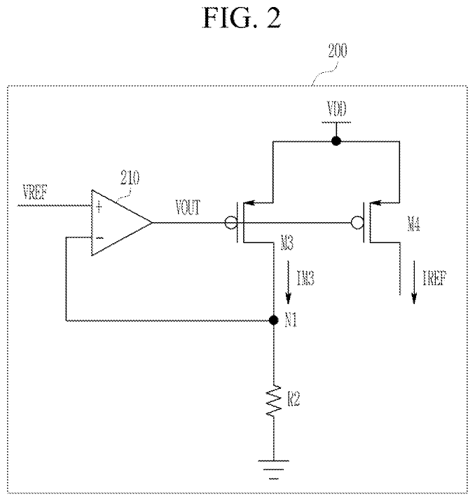

FIG. 2 illustrates a circuit diagram showing an example of the current source 112 illustrated in FIG. 1.

Referring to FIG. 2, the current source 200 may include an operational amplifier 210, a transistor M3, a transistor M4, and a resistor R2.

In FIG. 2, transistors M3 and M4 may be implemented as transistors such as, but not limited to, field effect transistors (FETs) and bipolar transistors. In FIG. 2, the transistors M3 and M4 are shown as p-type transistor. However, this is only an example, and the transistors M3 and M4 may be n-type transistors.

In the following description, for convenience, it is assumed that the transistors M3 and M4 are FETs. However, this is only an example, and the transistors M3 and M4 may be replaced with other transistors. In an example, the gate of the transistor may operate as a control terminal, so the gate of the transistor may be annotated as a ‘control terminal’. Since the source of the transistor is one terminal of the transistor, the source of the transistor may be annotated as a “first terminal” or “second terminal”. Since the drain of the transistor is also a terminal of the transistor, the drain of the transistor may be annotated as a “first terminal” or “second terminal”.

The operational amplifier 210 may have a non-inverting terminal +, an inverting terminal −, and an output terminal. A reference voltage VREF may be input to the non-inverting terminal + of the operational amplifier 210, and the inverting terminal—of the operational amplifier 210 may be connected to the node N1.

Due to the operation of the operational amplifier 210, the voltage of the inverting terminal − and the reference voltage VREF input to the non-inverting terminal + may be the same, so the voltage VOUT output from the operational amplifier 210 may be set so that the voltage of the non-inverting terminal + and the voltage of the inverting terminal − may be the same voltage.

An output terminal of the operational amplifier 210 may be connected to the gate of the transistor M3 and the gate of the transistor M4. That is, the voltage VOUT output from the operational amplifier 210 may be applied to the gate of the transistor M3 and the gate of the transistor M4. The source of the transistor M3 and the source of the transistor M4 may be connected to the power supply voltage VDD. In an example, the power supply voltage VDD may be a battery voltage.

The drain of the transistor M3 may be connected to the inverting terminal—of the operational amplifier 210 through the node N1.

The resistor R2 may be connected between the node N1 and ground.

A drain current IM3 of the transistor M3 may have the relationship of Equation 1 below.

$$IM 3 = \frac{{V}_{REF}}{R 2} \qquad Equation 1$$

Since the gate of the transistor M3 and the gate of the transistor M4 are connected to each other and the gate of the transistor M3 and the gate of the transistor M4 are connected to the output terminal of the operational amplifier 210, when the transistors M3 and M4 operate in the saturation region, the transistors M3 and M4 may have a current mirror structure. Accordingly, the current IREF output through the transistor M4 may have the relationship of Equation 2 below.

$$IREF = K 1 \times IM 3 \qquad Equation 2$$

In Equation 2, K1 may represent the size ratio of the transistor M3 and the transistor M4. In an example, if the size of transistor M4 is 10 times larger than the size of transistor M3, K1 may be 10.

Accordingly, the current source 200 may supply a constant current IREF even if the power supply voltage VDD changes. In other words, the voltage VREF input to the non-inverting terminal + has a fixed value even if the power supply voltage VDD changes, so the drain current IM3 of the transistor M3 also does not change even if the power supply voltage VDD changes, and accordingly, the current IREF may also have a constant value.

Additionally, in an example, the resistor R2 may have a temperature coefficient that satisfies PTAT characteristics. Accordingly, the performance of the LNA circuit 100 with respect to temperature may be compensated. In an example, the current source 200 may increase the current IREF as the temperature increases, and according to this characteristic, the resistance value of the resistor R2 may decrease as the temperature increases.

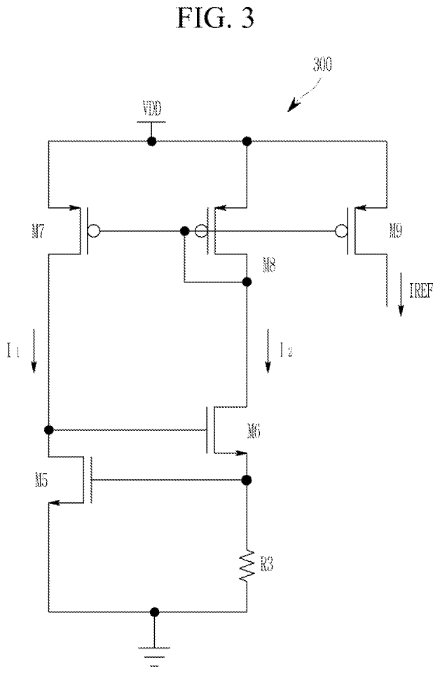

FIG. 3 illustrates a circuit diagram showing another example of the current source shown in FIG. 1.

Referring to FIG. 3, the current source 300 may include a transistor M5, a transistor M6, a transistor M7, a transistor M8, a transistor M9, and a resistor R3.

Various transistors such as, but not limited to, field effect transistors (FET) and bipolar transistors may be used as the transistor M5, transistor M6, transistor M7, transistor M8, and transistor M9.

In an example, the transistors M5 and M6 may be n-type transistors, and the transistors M7, M8, and M9 may be p-type transistors. This is an example, and transistor M5, transistor M6, transistor M7, transistor M8, and transistor M9 may be different types of transistors from those in FIG. 3.

The power supply voltage VDD may be input as a source of the transistor M8. Additionally, the power supply voltage VDD may also be input to a source of the transistor M7 and a source of the transistor M9.

A gate of transistor M8, a gate of transistor M7, and a gate of transistor M9 are connected in common, and the gate of transistor M8 and a drain of transistor M8 are connected to each other. That is, the transistor M8 may be connected in the form of a diode. Accordingly, the transistors M8 and M7, and the transistors M8 and M9 may have a current mirror structure, and the transistor M8 may supply the current I₂ from the power supply voltage VDD to the transistor M7 and transistor M9.

A drain of transistor M7 may be connected to a drain of transistor M5, and a source of transistor M5 may be connected to ground. The drain of transistor M8 may be connected to a drain of transistor M6, and a source of transistor M6 may be connected to ground. The resistor R3 may be connected between the source of the transistor M6 and ground. Additionally, a gate of transistor M5 may be connected to the source of transistor M6, and a gate of transistor M6 may be connected to the drain of transistor M5.

When the voltage between the gate of the transistor M5 and source of the transistor M5 is V_{GS1}, the current I₂ flowing through the transistor M8 may have the relationship of Equation 3 below.

$${I}_{2} = \frac{{V}_{G S 1}}{R 3} \qquad Equation 3$$

The voltage V_{GS1} between the gate of the transistor M5 and source of the transistor M5 and the current I₁ flowing through the transistor M7 may have the relationship of Equation 4 below.

$${I}_{1} = {μ}_{n} {{C}_{ox} ( \frac{W}{L} )}_{M 5} {( {V}_{GS 1} - {V}_{TH 1} )}^{2} \qquad Equation 4$$

In an example, W is the gate width of the transistor M5, and L is the gate length of the transistor M5. Cₒₓ may represent a gate-oxide film capacitance per unit area, and μₙ may represent an electron mobility. V_{TH1} may represent a threshold voltage of the transistor M5.

Equation 4 may be summarized as Equation 5 below, and the current I₂ flowing through the transistor M8 may be expressed as Equation 6 below.

$${V}_{GS 1} = \sqrt{\frac{2 {I}_{1} L}{μ {C}_{ox} W}} + {V}_{TH 1} \qquad Equation 5$$

$${I}_{2} = \frac{\sqrt{\frac{2 {I}_{1} L}{μ {C}_{ox} W}}}{R 3} + \frac{{V}_{T H 1}}{R 3} \qquad Equation 6$$

The transistors M8 and M7 have a current mirror structure, and if the sizes of the transistors M8 and M7 are the same, the magnitudes of the current I₁ and I₂ may be the same. Additionally, if the sizes of the transistors M8 and M9 are the same, the current IREF may be equal to the magnitude of the current I₂. Therefore, the current IREF flowing through the transistor M9 may be expressed as Equation 7.

$$IREF = {I}_{1} = {I}_{2} = \frac{{V}_{TH 1}}{R 3} + \frac{1}{{β}_{1} R {3}^{2}} + \frac{1}{R} \sqrt{\frac{2 {V}_{TH 1}}{{β}_{1} R 3} + \frac{1}{{β}_{1}^{2} R {3}^{2}}} \qquad Equation 7$$

In an example, β may be equal to Equation 8.

$$β = {μ}_{n} {C}_{ox} \frac{W}{L} \qquad Equation 8$$

As can be seen through Equation 7, since the current IREF may be not affected by the power supply voltage VDD, the current source 300 may supply a constant current IREF even if the power supply voltage VDD changes.

Additionally, in an example, the resistor R3 may have a temperature coefficient that satisfies PTAT characteristics. Accordingly, the performance of the LNA circuit 100 with respect to temperature may be compensated.

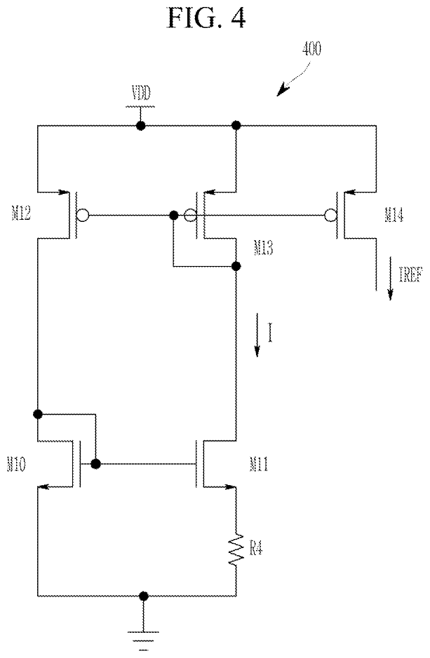

FIG. 4 illustrates a circuit diagram showing another example of the current source shown in FIG. 1.

Referring to FIG. 4, the current source 400 may include a transistor M10, a transistor M11, a transistor M12, a transistor M13, a transistor M14, and a resistor R4.

Various transistors such as, but not limited to, a field effect transistor FET and a bipolar transistor may be used as the transistor M10, the transistor M11, the transistor M12, the transistor M13, and the transistor M14.

In an example, the transistors M10 and M11 may be n-type transistors, and the transistors M12, M13, and M14 may be p-type transistors. This is only an example, and the transistors M10, M11, M12, M13, and M14 may be different types of transistors from those in FIG. 4.

The power supply voltage VDD may be input to a source of the transistor M13. Additionally, the power supply voltage VDD may also be input to a source of the transistor M12 and a source of the transistor M14.

A gate of transistor M12, a gate of transistor M13, and a gate of transistor M14 are connected in common, and the gate of transistor M13 and a drain of transistor M13 are connected to each other. That is, the transistor M13 may be connected in the form of a diode. Accordingly, the transistors M13 and M12, and the transistors M13 and M14 may have a current mirror structure, and the transistor M13 may supply the current I from the power supply voltage VDD to the transistor M12 and transistor M14.

A drain of transistor M12 may be connected to a drain of transistor M10, and a source of transistor M10 may be connected to ground. Additionally, the drain of transistor M10 may be connected to a gate of transistor M10. That is, the transistor M10 may be connected in the form of a diode.

The drain of transistor M13 may be connected to a drain of transistor M11, and a source of transistor M11 may be connected to ground. The resistor R4 may be connected between the source of the transistor M1 and ground. The gate of the transistor M10 may be connected to a gate of the transistor M11. Accordingly, the transistor M10 and transistor M11 may have a current mirror structure.

When the voltage between the gate of the transistor M10 and source of the transistor M10 is V_{GS1} and the voltage between the gate of the transistor M11 and source of the transistor M11 is V_{GS2}, the current I and the resistance of the resistance R4 may have the relationship of Equation 9 below.

$${V}_{GS 1} = {V}_{GS 2} + IR \qquad Equation 9$$

In Equation 9, R may represent the resistance value of the resistor R4.

Equation 9 may be converted to Equation 10 below.

$$( \sqrt{\frac{2 I}{{β}_{1}}} + VTH ) = ( \sqrt{\frac{2 I}{{β}_{2}}} + VTH ) + IR \\ ( \sqrt{\frac{2 I}{{β}_{1}}} + VTH ) = ( \sqrt{\frac{2 I}{K {β}_{1}}} + VTH ) + IR \qquad Equation 10$$

In an example, β₁ may be a parameter of the transistor M10, and β₂ may be a parameter of the transistor M11, and β₁ and β₂ may be obtained as in Equation 8.

If the sizes of the transistors M14 and M13 are the same, the current IREF may be equal to the current I, and may be expressed as Equation 11 below.

$$I = {I}_{ref} = \frac{2}{{R}^{2} {β}_{1}} \times {( 1 - \sqrt{\frac{1}{K}} )}^{2} \qquad Equation 11$$

As can be seen through Equation 11, since the current IREF may not be affected by the power supply voltage VDD, the current source 400 may supply a constant current IREF even if the power supply voltage VDD changes.

Additionally, in an example, the resistor R4 may have a temperature coefficient that satisfies PTAT characteristics. Accordingly, the performance of the LNA circuit 100 with respect to temperature may be compensated.

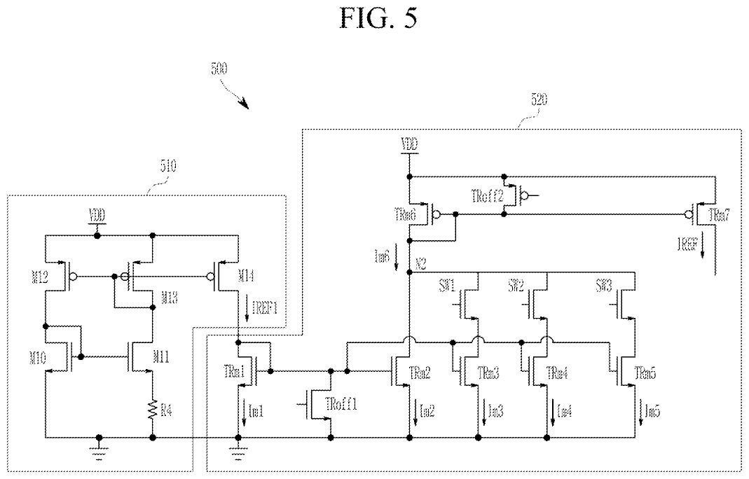

In an example, when the magnitude of the current IREF generated by the current sources 200, 300, and 400 illustrated in FIGS. 2 to 4 is small, the magnitude of the current IREF may be increased by combining a current mirror circuit with the circuits of the current sources 200, 300, and 400 described in FIGS. 2 to 4. This example is shown in FIG. 5.

FIG. 5 is a circuit diagram illustrating another example of the current source shown in FIG. 1.

Referring to FIG. 5, the current source 500 may include a current generation circuit 510 and a current mirror circuit 520.

The current generation circuit 510 may be one of the current source 200 shown in FIG. 2, the current source 300 shown in FIG. 3, or the current source 400 shown in FIG. 4. FIG. 5 illustrates the current source 400 shown in FIG. 4 as the current generation circuit 510.

The current mirror circuit 520 may mirror the current IREF1 generated by the current generation circuit 510 to generate a current IREF that is larger than the current IREF1.

The current mirror circuit 520 may include a plurality of mirroring transistors TRm1 to TRm7, switching elements SW1 to SW3, and transistors TRoff1 and TRoff2.

The mirroring transistors TRm1 to TRm5 may be n-type transistors, and the mirroring transistors TRm6 and TRm7 may be p-type transistors. The transistor TRoff1 may be an n-type transistor, and the transistor TRoff2 may be a p-type transistor. This may be one example.

A drain of the mirroring transistor TRm1 may be connected to the drain of the transistor M14 in the current generation circuit 510, a source of the mirroring transistor TRm1 may be connected to ground, and the drain and gate of the mirroring transistor TRm1 may be connected to each other. That is, the mirroring transistor TRm1 may be connected in the form of a diode.

The gates of the mirroring transistors TRm2 to TRm5 are connected to the gate of the mirroring transistor TRm1. The drains of the mirroring transistors TRm2 to TRm5 may be connected to the node N2, and the sources of the mirroring transistors TRm2 to TRm5 may be connected to ground. In an example, the switching element SW1 may be connected between the drain of the mirroring transistor TRm3 and a node N2, and the switching element SW2 may be connected between the drain of the mirroring transistor TRm4 and the node N2, and the switching element SW3 may be connected between the drain of the mirroring transistor TRm5 and the node N2. The magnitude of the current IREF may be adjusted depending on the on or off operation of each of the switching elements SW1 to SW3.

The power supply voltage VDD may be input to a source of the mirroring transistor TRm6. Additionally, the power supply voltage VDD may also be input to a source of the transistor TRm7.

A drain of the mirroring transistor TRm6 may be connected to the node N2, a gate of the mirroring transistor TRm7 may be connected to a gate of the mirroring transistor TRm6, and the drain of the mirroring transistor TRm6 and the gate of mirroring transistor TRm6 may be connected to each other. The current IREF may be output through a drain of the mirroring transistor TRm7.

Since the mirroring transistor TRm6 may be connected in the form of a diode, the mirroring transistor TRm6 and the mirroring transistor TRm7 may have a current mirror structure, and the mirroring transistor TRm6 may supply the current Im6 from the power supply voltage VDD to the mirroring transistor TRm7.

At this time, the current Im6 is the sum of the currents Im2 to Im5 flowing through the mirroring transistors TRm2 to TRm5, and the magnitude of the current Im6 may be adjusted depending on the on or off operation of each of the switching elements SW1 to SW3.

The currents Im2 to Im5 flowing through the mirroring transistors TRm2 to TRm5 may be determined based on the current Im1 flowing through the mirroring transistor TRm1.

The current Im1 flowing through the mirroring transistor TRm1 may be determined according to the current IREF1 output from the current generation circuit 510.

In an example, if the sizes of the mirroring transistors TRm1 to TR7 are the same and the switching elements SW1 to SW3 are all turned on, the current IREF may be four times the magnitude of the current Im1.

The transistor TRoff1 may be connected between the gate of the mirroring transistor TRm1 and ground, and the transistor TRoff2 may be connected between the power supply voltage VDD and the gate of the mirroring transistor TRm6.

The transistors TRoff1 and TRoff2 may block the supply of current IREF in an off mode of the LNA circuit 100. The transistors TRoff1 and TRoff2 may be turned on to turn off the bias circuit 110 in the off mode of the LNA circuit 100. When the LNA circuit 100 is turned off, the transistors TRoff1 and TRoff2 may be turned on, and accordingly, OV may be applied to the gates of the mirroring transistors TRm1 to TRm5, and the power supply voltage VDD may be applied to the mirroring transistors TRm6 and TRm7, and accordingly all mirroring transistors TRm1 to TRm7 may be turned off.

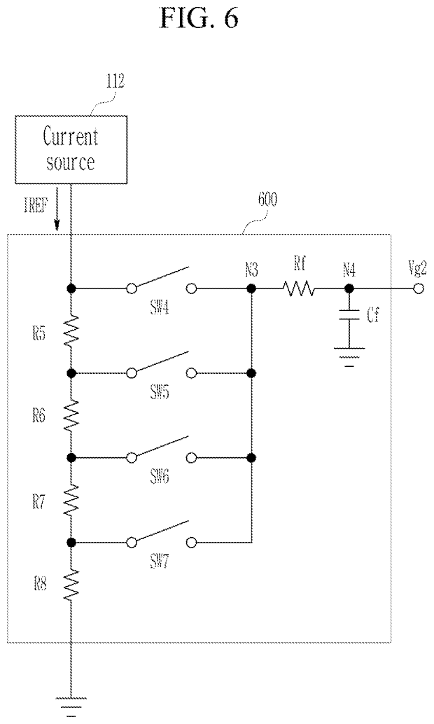

FIG. 6 is a diagram illustrating an example of the current-to-voltage conversion circuit shown in FIG. 1.

Referring to FIG. 6, the current-to-voltage conversion circuit 600 may include a plurality of resistors R5 to R8, a plurality of switches SW4 to SW7, a resistor (Rf), and a capacitor Cf.

The plurality of resistors R5 to R8 may be connected in series between an output terminal of the current source 112 and ground.

The switch SW4 may be connected between a first end of the resistor R5, that is, the output terminal of the current source 112 and a node N3.

The switch SW5 may be connected between a second end of the resistor R5, that is, a first end of the resistor R6 and the node N3.

The switch SW6 may be connected between a second end of the resistor R6, that is, a first end of the resistor R6 and the node N3.

The switch SW7 may be connected between a second end of the resistor R7, that is, a first end of the resistor R8 and the node N3.

The resistor Rf may be connected between the node N3 and the node N4, and the capacitor Cf may be connected between the node N4 and ground. The node N4 may be an output terminal of the current-to-voltage conversion circuit 600 and may be connected to the gate of the transistor M2 shown in FIG. 1.

This current-to-voltage conversion circuit 600 may generate the gate bias voltage Vg2 applied to the gate of the transistor M2 from the input current IREF, and may adjust the voltage magnitude of the gate bias voltage Vg2 applied to the gate of the transistor M2 according to the on and/or off operation of the switches SW4 to SW7.

In an example, if a constant current IREF from the current source 112 is input to the current-voltage conversion circuit 600 and only the switch SW4 is turned on, the gate bias voltage Vg2 applied to the gate of the transistor M2 may be expressed as Equation 12 below.

$$Vg 2 = ( R 5 + R 6 + R 7 + R 8 ) \times IREF \qquad Equation 12$$

As shown in Equation 12, if the current IREF is constant, the voltage Vg2 applied to the gate of the transistor M2 may have a constant voltage regardless of the power supply voltage VDD.

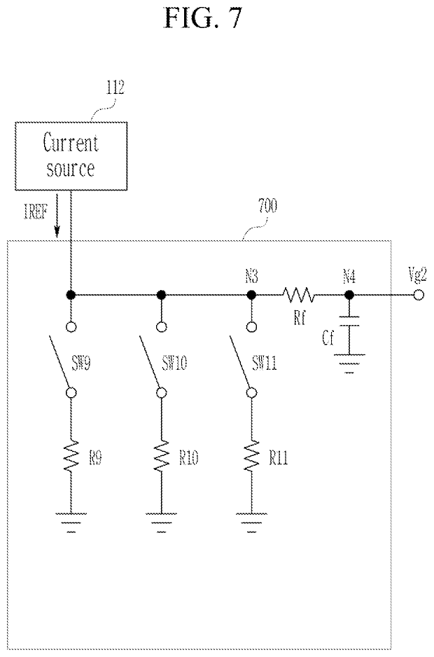

FIG. 7 is a diagram showing another example of the current-to-voltage conversion circuit shown in FIG. 1.

Referring to FIG. 7, the current-to-voltage conversion circuit 700 may include a plurality of resistors R9, R10, and R11, a plurality of switches SW9, SW10, and SW11, a resistor Rf, and a capacitor Cf.

The resistors R9, R10, and R11 may each be connected in series between the output terminal of the current source 112 and ground.

The switch SW9 may be connected between a node N3, that is, the output terminal of the current source 112 and the resistor R9, and the switch SW10 may be connected between the output terminal of the current source 112 and the resistor R10, and the switch SW11 may be connected between the output terminal of the current source 112 and the resistor R11.

The resistor Rf may be connected between the output terminal of the current source 112 and the node N4, and the capacitor Cf may be connected between the node N4 and ground. The node N4 may be an output terminal of the current-to-voltage conversion circuit 700 and may be connected to the gate of the transistor M2 shown in FIG. 1.

This current-to-voltage conversion circuit 700 may generate the gate bias voltage Vg2 applied to the gate of the transistor M2 from the input current IREF, and may adjust the voltage magnitude of the gate bias voltage Vg2 applied to the gate of the transistor M2 according to the on and/or off of the switches SW9, SW10, and SW10.

In an example, if a constant current IREF from the current source 112 is input to the current-to-voltage conversion circuit 700 and only the switch SW9 is turned on, the gate bias voltage Vg2 applied to the gate of the transistor M2 may be expressed as Equation 13 below.

$$Vg 2 = R 9 \times IREF \qquad Equation 13$$

In another example, if a constant current IREF from the current source 112 is input to the current-to-voltage conversion circuit 700 and the switches SW9 and SW10 are turned on, the gate bias voltage Vg2 applied to the gate of the transistor M2 may be expressed as Equation 14 below.

$$Vg 2 = \frac{( R 9 \times R 10 )}{R 9 + R 10} \times IREF \qquad Equation 14$$

As shown in Equation 13 and Equation 14, if the current IREF is constant, the gate bias voltage Vg2 applied to the gate of the transistor M2 may have a constant voltage regardless of the power supply voltage VDD.

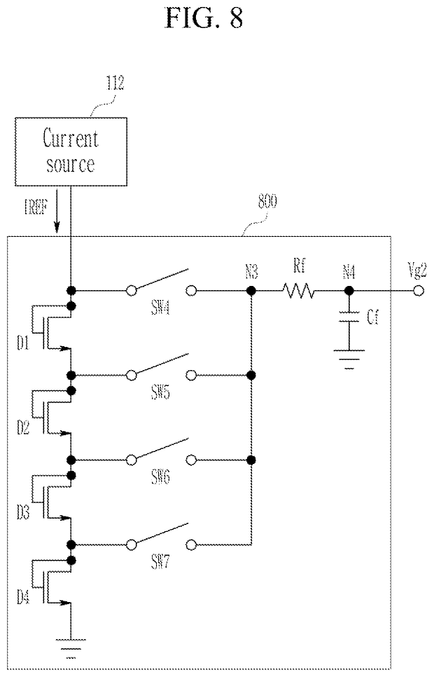

FIG. 8 is a diagram showing another example of the current-to-voltage conversion circuit shown in FIG. 1.

Referring to FIG. 8, the current-to-voltage conversion circuit 800 may include a plurality of diode-connected transistors D1, D2, D3, and D4 instead of the plurality of resistors R5, R6, R7, and R8 shown in FIG. 6. That is, the plurality of diode-connected transistors D1, D2, D3, and D4 may be connected in series between the output terminal of the current source 112 and ground.

This current-to-voltage conversion circuit 800 may generate the gate bias voltage Vg2 applied to the gate of the transistor M2 from the input current IREF, and may adjust the voltage magnitude of the gate bias voltage Vg2 applied to the gate of the transistor M2 according to the on and/or off operations of the switches SW4 to SW7. At this time, if the current IREF is constant, the gate bias voltage Vg2 applied to the gate of the transistor M2 may have a constant voltage regardless of the power supply voltage VDD.

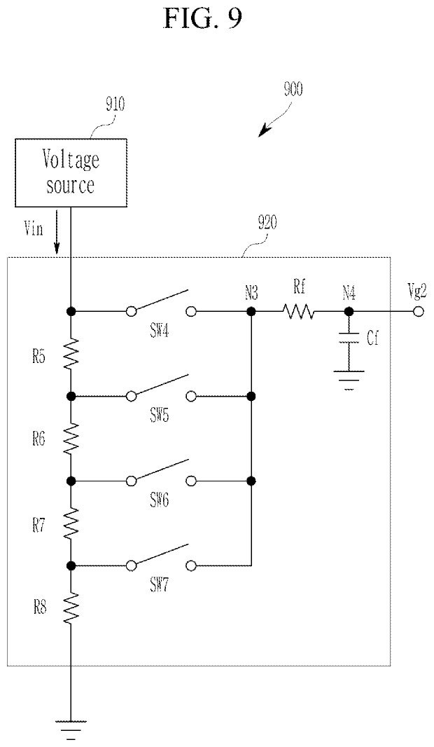

FIG. 9 is a diagram showing an example of a bias circuit having a voltage source. In accordance with one or more embodiments.

As illustrated in FIG. 9, the bias circuit 900 may include a voltage source 910 and a voltage division circuit 920.

The voltage source 910 may supply a voltage Vin from the power supply voltage VDD. In one example, the voltage source 910 may generate the voltage Vin from the power supply voltage VDD using a low dropout (LDO) circuit and provide the voltage Vin to the voltage division circuit 920.

The voltage division circuit 920 may convert the voltage Vin supplied from the voltage source 910 into a predetermined voltage and provide converted voltage to the gate of the transistor M2 as the gate bias voltage Vg2. This voltage division circuit 920 may be the same or similar to the current-to-voltage conversion circuit 600 shown in FIG. 6.

Unlike the previously described embodiments, the bias circuit 900 shown in FIG. 9 may use a voltage source 910 and may provide the gate bias voltage Vg2 through the voltage division circuit 920.

However, when the voltage source 910 is used, the gate bias voltage Vg2 may vary as the power supply voltage VDD changes.

In an example, when the switch SW5 is turned on and the remaining switches SW4, SW6, and SW7 are turned off, the gate bias voltage Vg2 by the bias circuit 900 shown in FIG. 9 may be expressed as Equation 15 below.

$$Vg 2 = \frac{R 6 + R 7 + R 8}{R 5 + R 6 + R 7 + R 8} \times {V}_{i n} \qquad Equation 15$$

As shown in Equation 15, the bias circuit 900 may be dependent on the voltage Vin supplied from the voltage source 910, and when the power supply voltage VDD is varied, the voltage Vin may be varied, and accordingly, the gate bias voltage Vg2 may also be changed.

Typically, the power supply voltage VDD may be 1.2V or 1.8V, and the bias circuit 900 may provide a gate bias voltage Vg2 dependent on the power supply voltage VDD. Accordingly, it may be difficult to supply a constant voltage to the gate of transistor M2. On the other hand, if the current source may be used as in the embodiment, a constant current IREF may be supplied even if the power supply voltage VDD changes, and therefore a constant gate bias voltage may be supplied to the gate of the transistor M2.

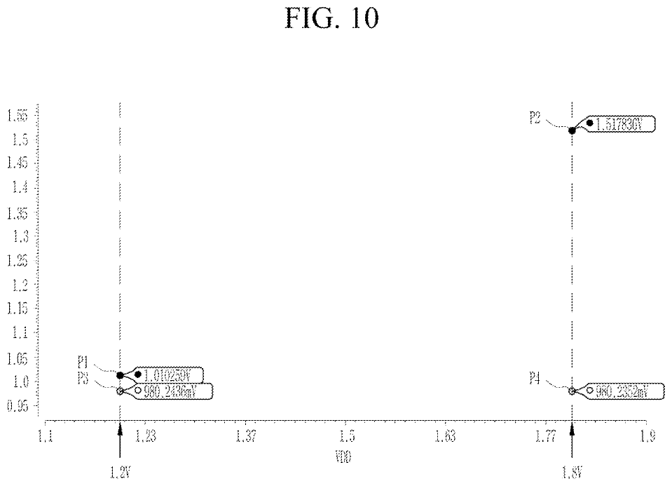

FIG. 10 is a diagram illustrating gate bias voltages provided from the bias circuit shown in FIG. 9 and the bias circuit shown in FIG. 1, respectively.

In FIG. 10, the gate bias voltage P1 may represent the voltage output from the bias circuit 900 shown in FIG. 9 when the power supply voltage VDD is 1.2V, the gate bias voltage P2 may represent the voltage output from the bias circuit 900 shown in FIG. 9 when the power supply voltage VDD is 1.8V. The gate bias voltage P3 may represent the voltage output from the bias circuit 110 shown in FIG. 1 when the power supply voltage VDD is 1.2V, the gate bias voltage P4 may represent the voltage output from the bias circuit 110 shown in FIG. 1 when the power supply voltage VDD is 1.8V. At this time, the current-voltage conversion circuit 600 shown in FIG. 6 was used as the current-voltage conversion circuit 114, and the current source 300 shown in FIG. 3 was used as the current source 112.

As illustrated in FIG. 10, in the example of the bias circuit 900 shown in FIG. 9, it may be seen that the gate bias voltages P1 and P3 change from about 1.01V to about 1.52V as the power supply voltage VDD changes from 1.2V to 1.8V. On the other hand, in the bias circuit 110 according to the embodiment, the gate bias voltages P2 and P4 may be seen to be constant at about 0.98V regardless changes in the power supply voltage VDD.

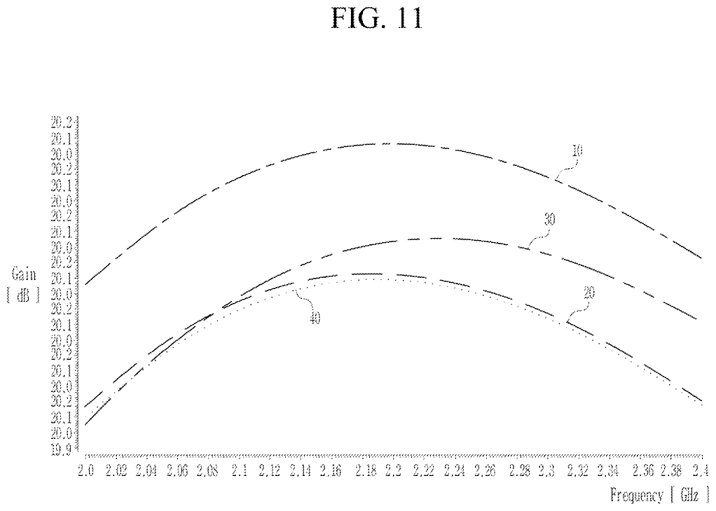

FIG. 11 is a graph showing the gain characteristics of the LNA circuit including the bias circuit shown in FIG. 9 and the gain characteristic of the LNA circuit including the bias circuit shown in FIG. 1.

In FIG. 11, the gain characteristics 20 may represent gain characteristics of the LNA circuit including the bias circuit 900 shown in FIG. 9 at the power supply voltage VDD of 1.2V, the gain characteristics 40 may represent gain characteristics of the LNA circuit including the bias circuit 110 shown in FIG. 1 at the power supply voltage VDD of 1.2 V. The gain characteristics 10 may represent gain characteristics of the LNA circuit including the bias circuit 900 shown in FIG. 9 at the power supply voltage VDD of 1.8V, the gain characteristics 30 may represent gain characteristics of the LNA circuit including the bias circuit 110 shown in FIG. 1 at the power supply voltage VDD of 1.8 V. At this time, the current-voltage conversion circuit 600 shown in FIG. 6 was used as the current-voltage conversion circuit 114, and the current source 300 shown in FIG. 3 was used as the current source 112.

As shown in FIG. 11, it can be seen that the LNA circuit including the bias circuit 110 has a smaller gain change than the LNA circuit including the bias circuit 900.

Additionally, In the example of the bias circuit 900 that uses the voltage of the voltage source 910 by dividing the voltage with resistance, it is impossible to compensate for the performance of the LNA circuit according to temperature changes because the resistance characteristics change equally depending on temperature.

On the other hand, as in the embodiment, the bias circuit 110 having the current source 110 may be implemented to operate in PTAT to compensate performance against temperature. Therefore, changes in the performance of the LNA circuit depending on temperature may be reduced.

In an example, the temperature coefficient for the current IREF of the current source 300 shown in FIG. 3 may be expressed as Equation 16 below.

$${TC}_{I} = \frac{1}{IREF} \frac{dIREF}{dT} = - 2 \times TCR + \frac{1.5}{T} \qquad Equation 16$$

In an example, TCR may represent the temperature coefficient of the resistance R3 shown in FIG. 3.

As shown in Equation 16, the temperature coefficient TC, for the current IREF may be determined through the temperature coefficient of the resistance R3. Therefore, by using a resistor R3 that can provide the desired performance according to changes in temperature, it is possible to implement a current source 300 that operates with PTAT characteristics, and thus performance changes of the LNA circuit according to temperature may be reduced.

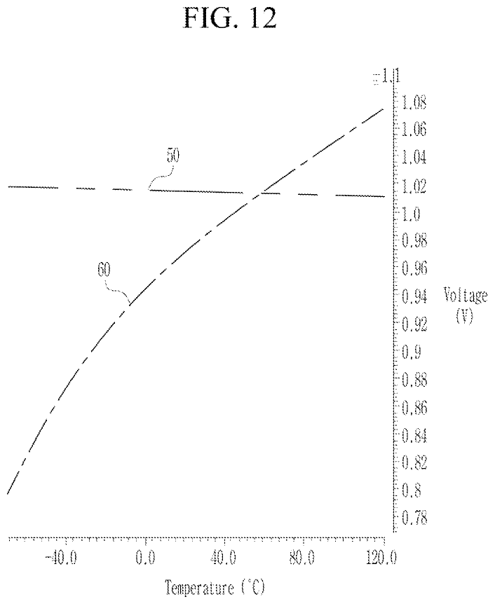

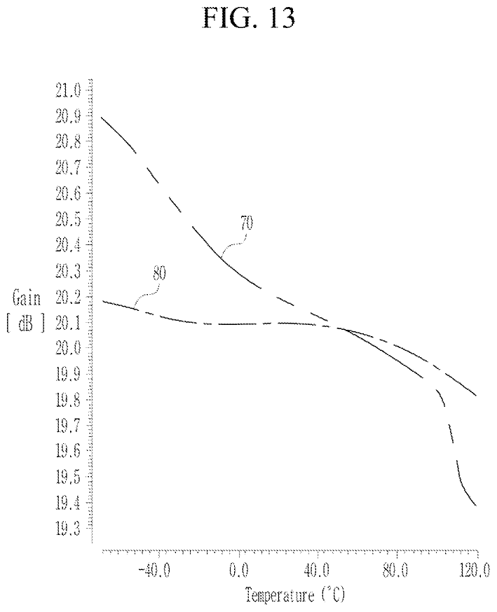

FIG. 12 is a diagram illustrating the gate bias voltages provided by the bias circuit shown in FIG. 9 and the bias circuit shown in FIG. 6, respectively, according to temperature, and FIG. 13 is a graph showing the gain characteristics of the LNA circuit including the bias circuit shown in FIG. 9 and the LNA circuit including the bias circuit shown in FIG. 1 according to temperature.

In FIGS. 12 and 13, a power supply voltage VDD of 1.2V was used.

As shown in FIG. 12, the bias circuit 110 may provide a gate bias voltage 60 that increases as the temperature increases, and the bias circuit 900 may provide a gate bias voltage 50 that gradually decreases as the temperature increases. Accordingly, as shown in FIG. 13, it can be seen that as the temperature increases, the change in the gain characteristic 80 of the LNA circuit including the bias circuit 110 shown in FIG. 1 is smaller than the change in the gain characteristic 70 of the LNA circuit including the bias circuit 900 shown in FIG. 9, as the temperature increases.

Additionally, when using the voltage source 910 as shown in FIG. 9, an LDO circuit that generates a constant voltage or a circuit with a similar operation to the LDO circuit must be used to reduce the characteristic deviation depending on the power supply voltage, however this can reduce the voltage, which may result in performance loss. Additionally, because the area occupied by the LDO circuit is large, it is difficult to miniaturize the IC.

On the other hand, if the current source 110 is used as in the embodiment, a constant gate voltage may be supplied without the LDO circuit, and there may also be a benefit in the design area of the LNA circuit.

According to at least one of the embodiments, a constant bias voltage may be provided by providing a constant reference current even if the power supply voltage changes. Accordingly, even if the power supply voltage changes, the change in gain characteristics of the low noise amplifier circuit may be reduced.

Additionally, according to at least one of the embodiments, a bias voltage adjusted according to temperature changes may be provided by adjusting the magnitude of the reference current according to temperature changes. As a result, the change in gain characteristics of the low noise amplifier circuit depending on temperature may be reduced.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bias circuit, connected to a first transistor configured to amplify an input radio frequency (RF) signal, and configured to provide a bias voltage to a second transistor that amplifies an output RF signal of the first transistor, the bias circuit comprising:
a current source configured to receive a power supply voltage and generate a reference current; and
a current-to-voltage conversion circuit configured to convert the reference current into the bias voltage and provide the bias voltage to a control terminal of the second transistor.

2. The bias circuit of claim 1, wherein:
the current source is configured to increase a magnitude of the reference current as temperature increases.

3. The bias circuit of claim 1, wherein:
the current source comprises:
a third transistor configured to have a first terminal connected to the power supply terminal that supplies the power supply voltage, and a second terminal connected to a ground through a resistor; and
a fourth transistor connected to the third transistor in a current mirror structure and configured to generate the reference current by mirroring a current of the third transistor,
wherein a resistance value of the resistor decreases as temperature increases.

4. The bias circuit of claim 3, wherein:
the current source further comprises:
an operation amplifier configured to have a first terminal to which a reference voltage is applied, a second terminal connected to the second terminal of the third transistor, and an output terminal connected to a control terminal of the third transistor and a control terminal of the fourth transistor, and configured to operate so that a voltage of the second terminal of the operational amplifier is equal to the reference voltage.

5. The bias circuit of claim 3, wherein:
the current source further comprises:
a fifth transistor configured to have a first terminal connected to the power supply terminal and connected to the third transistor in a current mirror structure;
a sixth transistor configured to have a first terminal connected to the second terminal of the third transistor, a second terminal connected to the resistor, and a control terminal connected to a second terminal of the fifth transistor; and
a seventh transistor connected between the second terminal of the fifth transistor and the ground, and configured to have a control terminal connected to the second terminal of the sixth transistor.

6. The bias circuit of claim 3, wherein:
the current source further comprises:
a fifth transistor configured to have a first terminal connected to the power supply terminal and connected to the third transistor in a current mirror structure;
a sixth transistor diode-connected between a second terminal of the fifth transistor and the ground; and
a seventh transistor configured to have a first terminal connected to the second terminal of the third transistor, a second terminal connected to the resistor, and a control terminal connected to a control terminal of the sixth transistor.

7. The bias circuit of claim 1, wherein:
the current-to-voltage conversion circuit further comprises:
a plurality of resistors connected in series between the current source and a ground; and
a plurality of switches connected between one end of each of the plurality of resistors and a control terminal of the second transistor.

8. The bias circuit of claim 1, wherein:
the current-to-voltage conversion circuit further comprises:
a plurality of resistors connected in parallel between the current source and a ground; and
a plurality of switches connected between one end of each of the plurality of resistors and the current source.

9. The bias circuit of claim 1, wherein:
the current-to-voltage conversion circuit further comprises:
a plurality of diodes connected in series between the current source and a ground; and
a plurality of switches connected between one end of each of the plurality of diodes and a control terminal of the second transistor.

10. A low noise amplifier circuit, comprising:
a common source transistor configured to amplify an input radio frequency (RF) signal and output an amplified RF signal;
a common gate transistor, connected to the common source transistor with a cascode structure, configured to operate based on a bias voltage input to a control terminal, and configured to amplify and output an output RF signal of the common source transistor; and
a bias circuit configured to generate a reference current from a power supply voltage and configured to generate the bias voltage with the reference current.

11. The low noise amplifier circuit of claim 10, wherein:
the bias circuit comprises:
a current source configured to receive the power supply voltage and configured to generate the reference current; and
a current-to-voltage conversion circuit configured to convert the reference current into the bias voltage and configured to provide the bias voltage to a control terminal of the common gate transistor,
wherein the current source is configured to increase a magnitude of the reference current as temperature increases.

12. The low noise amplifier circuit of claim 11, wherein:
the current source comprises:
a third transistor configured to have a first terminal connected to the power supply terminal that supplies the power supply voltage, and a second terminal connected to a ground through a resistor; and
a fourth transistor connected to the third transistor in a current mirror structure and configured to generate the reference current by mirroring a current of the third transistor,
wherein a resistance value of the resistor decreases as temperature increases.

13. The low noise amplifier circuit of claim 12, wherein:
the current source further comprises:
an operation amplifier configured to have a first terminal to which a reference voltage is applied, a second terminal connected to the second terminal of the third transistor, and an output terminal connected to a control terminal of the third transistor and a control terminal of the fourth transistor, and configured to operate so that the voltage of the second terminal is equal to the reference voltage.

14. The low noise amplifier circuit of claim 12, wherein:
the current source further comprises:
a fifth transistor configured to have a first terminal connected to the power supply terminal and connected to the third transistor in a current mirror structure;
a sixth transistor configured to have a first terminal connected to the second terminal of the third transistor, a second terminal connected to the resistor, and a control terminal connected to a second terminal of the fifth transistor; and
a seventh transistor connected between the second terminal of the fifth transistor and ground, and configured to have a control terminal connected to the second terminal of the sixth transistor.

15. The low noise amplifier circuit of claim 12, wherein:
the current source further comprises:
a fifth transistor configured to have a first terminal connected to the power supply terminal and connected to the third transistor in a current mirror structure;
a sixth transistor diode-connected between a second terminal of the fifth transistor and the ground; and
a seventh transistor configured to have a first terminal connected to the second terminal of the third transistor, a second terminal connected to the resistor, and a control terminal connected to a control terminal of the sixth transistor.

16. The low noise amplifier circuit of claim 11, wherein:
the current-to-voltage conversion circuit comprises a plurality of resistors connected between the current source and ground, and configured to convert the reference current into the bias voltage, and
the bias voltage is generated by at least some of the plurality of resistors.
